(19) United States
(12) Patent Application Publication
(10) Pub. No.: US 2024/0244717 A1
(43) Pub. Date: Jul. 18, 2024

(54) HEAT TREATMENT CHAMBER, FILM FORMING APPARATUS, AND SUBSTRATE HEATING METHOD

(71) Applicants: Resonac Corporation, Tokyo (JP); Ushio Denki Kabushiki Kaisha, Tokyo (JP)

(72) Inventors: Gohei KUROKAWA, Chiba (JP); Haruhisa OHASHI, Chiba (JP); Takahiro INOUE, Tokyo (JP)

(21) Appl. No.: 18/407,627

(22) Filed: Jan. 9, 2024

(30) Foreign Application Priority Data
Jan. 18, 2023 (JP) 2023-005931

(51) Int. Cl. H05B 3/00; G11B 5/84

(52) U.S. Cl. CPC H05B 3/0038; G11B 5/84

(57) ABSTRACT

A heat treatment chamber for performing a heat treatment on a substrate, includes a chamber housing surrounding the substrate, a light transmitting window forming a part of the chamber housing, and an LED light source, provided on an outer side of the chamber housing, and configured to irradiate light on the substrate arranged inside the chamber housing through the light transmitting window, so to perform the heat treatment on the substrate.

### CROSS-REFERENCE TO RELATED APPLICATIONS

This application is based upon and claims priority to Japanese Patent Application No. 2023-005931 filed on Jan. 18, 2023, the entire contents of which are incorporated herein by reference.

### BACKGROUND OF THE INVENTION

### 1. Field of the Invention

The present disclosure relates to heat treatment chambers, film forming apparatuses, and substrate heating methods.

The heat treatment chamber is sometimes also referred to as a heat-treating chamber. The film forming apparatus is sometimes also referred to as a deposition apparatus.

### 2. Description of the Related Art

Conventionally, there is a known film forming apparatus which performs a heat treatment on a substrate, using a heating means, such as a halogen lamp or the like, installed in a chamber (refer to Japanese Laid-Open Patent Publication No. 2011-044537, for example).

However, according to the heating means described in Patent Document 1, a large amount of gas (degassing) is emitted from a heat source, and the degassing may become incorporated into the substrate, to thereby form an oxide or the like on the substrate surface, for example. Further, because a directivity of heat rays emitted from the heat source of such a heating means is low and the heating means heats members other than the substrate, degassing emitted from the members other than the substrate may also adversely affect the heat treatment on the substrate.

### SUMMARY OF THE INVENTION

In view of the above problem, one object of a technique according to the present disclosure is to reduce degassing, so as to improve a quality of a film formed on a substrate.

According to one aspect of the disclosure, a heat treatment chamber for performing a heat treatment on a substrate, includes a chamber housing surrounding the substrate; a light transmitting window forming a part of the chamber housing; and an LED light source, provided on an outer side of the chamber housing, and configured to irradiate light on the substrate arranged inside the chamber housing through the light transmitting window, so to perform the heat treatment on the substrate.

According to another aspect of the disclosure, a film forming apparatus includes a heat treatment chamber configured to perform a heat treatment on a substrate; a carrier configured to support an outer peripheral end portion of the substrate by a plurality of support members inside the heat treatment chamber, and hold the substrate by an opening of a substrate holder to which the plurality of support members are attached; a transfer mechanism configured to transfer the carrier into the heat treatment chamber, wherein the heat treatment chamber includes a chamber housing surrounding the substrate held by the carrier; a light transmitting window forming a part of the chamber housing; and an LED light source, provided on an outer side of the chamber housing, and configured to irradiate light on the substrate arranged inside the chamber housing through the light transmitting window, so to perform the heat treatment on the substrate.

According to still another aspect of the present disclosure, a substrate heating method includes irradiating light from an LED light source provided on an outer side of a chamber housing onto a substrate arranged inside the chamber housing through a light transmitting window, so to perform a heat treatment on the substrate.

Other objects and further features of the present invention will be apparent from the following detailed description when read in conjunction with the accompanying drawings.

### BRIEF DESCRIPTION OF THE DRAWINGS

FIG. 1 is a cross sectional view of a recording medium manufactured by a film forming apparatus according to one embodiment;

FIG. 2 is a plan view of the film forming apparatus according to one embodiment;

FIG. 3 is a side view of a chamber of the film forming apparatus according to one embodiment;

FIG. 4 is a side view of a carrier of the film forming apparatus according to one embodiment;

FIG. 5A is a cross sectional view of a heat treatment chamber according to one embodiment;

FIG. 5B is a side view of the heat treatment chamber according to one embodiment; and

FIG. 6 is a perspective view of an LED light source used in the heat treatment chamber according to one embodiment.

### DESCRIPTION OF THE PREFERRED EMBODIMENTS

Hereinafter, embodiments of the present disclosure will be described in detail with reference to the drawings. The same constituent elements in the drawings are designated by the same reference numerals, and a repeated description of the same constituent elements will be omitted, as appropriate.

In recent years, the application range or field of magnetic storage apparatuses has increased considerably, increasing the importance of the magnetic storage apparatuses, and the recording density of magnetic recording media used in the magnetic storage apparatuses has improved remarkably.

An example of a manufacturing method for manufacturing the magnetic recording medium includes forming a soft magnetic layer, an intermediate layer, a recording magnetic layer, or the like on a non-magnetic substrate, and thereafter forming a protective layer on the recording magnetic layer, for example.

In such a manufacturing method, it is preferable to continuously perform processes or treatments using a single film forming apparatus, if possible. By continuously performing the processes or treatments, contamination of the substrate during handling can be prevented. In addition, the efficiency of the manufacturing process and the product yield can be improved by reducing or eliminating handling processes, to thereby increase the productivity of the magnetic recording medium.

Accordingly, when manufacturing the magnetic recording medium, there is a proposal to use an in-line film forming apparatus that successively forms magnetic layers or the like on both surfaces of a non-magnetic substrate, while successively transporting a carrier holding a plurality of non-magnetic substrates into a plurality of chambers.

The manufacturing process of the magnetic recording medium includes a process of performing a heat treatment on the substrate formed with the film. In an example of the heat treatment, the substrate is heated to increase the heating temperature during the formation of a perpendicular magnetic layer, so as to improve a crystal orientation of the perpendicular magnetic layer, and thus increase the recording density of the magnetic recording medium.

Conventionally, during the heat treatment on the substrate formed with the film, one of heating means, such as a halogen lamp heater, a ceramic heater, a resistance heater, or the like provided inside the chamber is used. However, such heating means emit a large amount of degassing from a heat source, and the degassing may become incorporated into the substrate, to thereby form an oxide or the like on the substrate surface, for example.

Further, because a directivity of heat rays emitted from the heat source of such heating means is low and the heating means heat members other than the substrate, the degassing emitted from the members other than the substrate may also adversely affect the heat treatment on the substrate. The members other than the substrate include a substrate holder, the carrier, an inner wall of a chamber housing, or the like, for example. Further, it is necessary to provide, inside the chamber, a reflection plate for reflecting heat rays and a shield plate for protecting a member that is easily affected by the heat. Consequently, degassing from the reflection plate and the shield plate also adversely affects the film formation.

In particular, as the application range or field of magnetic storage apparatuses increases, there are demands to further improve the recording density of the magnetic recording media, thereby causing heating temperatures during the formation of magnetic layer to further increase with the improvement of the recording density. As a result, the adverse effects of the degassing from members inside a heat treatment chamber can no longer be ignored.

In the present embodiment, a technique for reducing the degassing will be described by referring to an example in which the magnetic recording medium to be provided in a hard disk drive (HDD) is manufactured using the in-line film forming apparatus that performs film forming processes by successively transporting a disk-shaped substrate into a plurality of chambers.

### Configuration Example of Magnetic Recording Medium

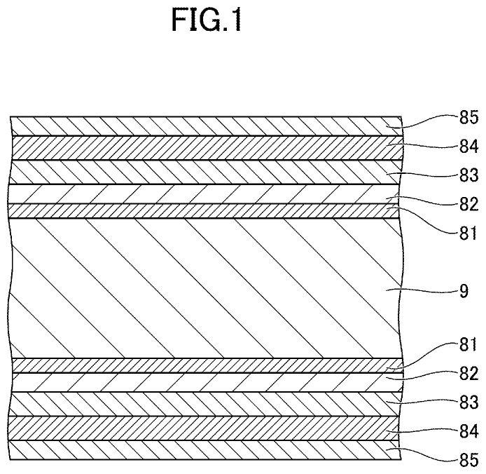

FIG. 1 is a cross sectional view of a recording medium manufactured by a film forming apparatus according to one embodiment. In this example, the recording medium is a magnetic recording medium, for example.

The magnetic recording medium has a structure including a soft magnetic layer 81, an intermediate layer 82, a recording magnetic layer 83, and a protective layer 84 are successively laminated on both of two mutually opposite surfaces of a disk-shaped substrate 9, and a lubricant film 85 formed at mutually opposite outermost surfaces of the magnetic recording medium. In FIG. 1, the two mutually opposite surfaces of the disk-shaped substrate 9 refer to upper and lower surfaces of the disk-shaped substrate 9.

Examples of the disk-shaped substrate 9 include an Al alloy substrate formed of an Al-Mg alloy or the like including Al as a main component, and a substrate formed of any one of ordinary soda glass, aluminosilicate-based glass, crystallized glass, silicon, titanium, ceramics, various resins, or the like. That is, an arbitrary non-magnetic substrate may be used as the disk-shaped substrate 9.

### Configuration Example of In-Line Film Forming Apparatus

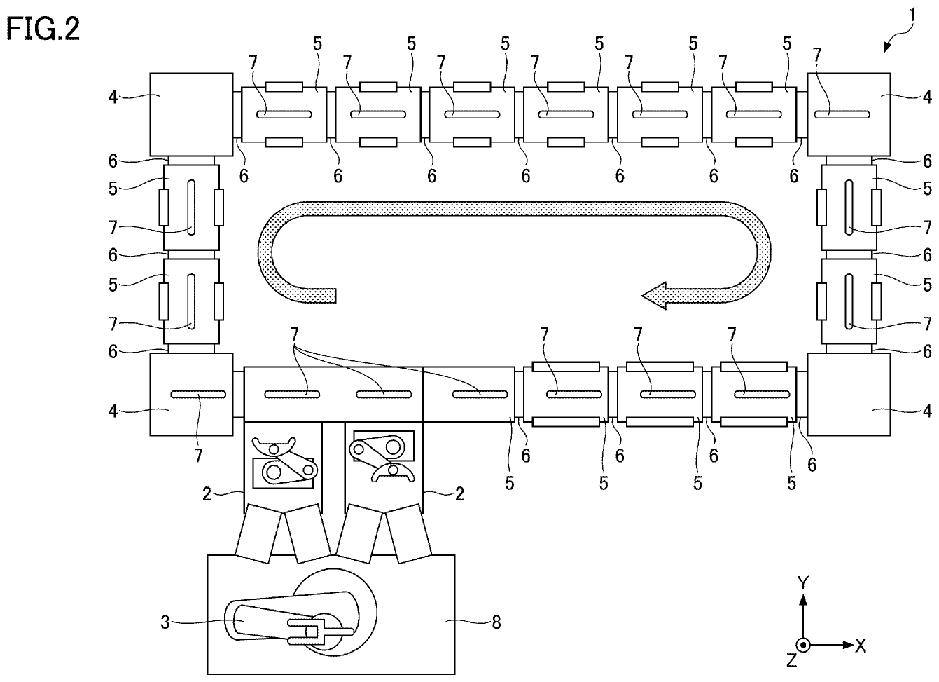

FIG. 2 is a plan view of the film forming apparatus according to one embodiment. When manufacturing a magnetic recording medium, at least the soft magnetic layer 81, the intermediate layer 82, the recording magnetic layer 83, and the protective layer 84 are successively laminated on both of the two mutually opposite surfaces of a disk-shaped substrate 9 to be subjected to the film formation, for example, using an in-line film forming apparatus 1 illustrated in FIG. 2. In this laminating process or step, the in-line film forming apparatus 1 performs a heat treatment on the disk-shaped substrate 9 before the film formation or the disk-shaped substrate 9 after the film formation. By performing such a heat treatment, the magnetic recording medium can be manufactured with a high productivity.

More particularly, the in-line film forming apparatus 1 includes a robot base 8, a substrate cassette transfer robot 3 placed on the robot base 8, a substrate attaching and detaching robot 2 adjacent to the robot base 8, and a plurality of corner chambers 4 for rotating a carrier 7. In addition, the in-line film forming apparatus 1 includes a plurality of chambers 5 arranged between the corner chambers 4, and a plurality of carriers 7 successively transported through the plurality of corner chambers 4 and the plurality of chambers 5.

Gate valves 6 are provided at connecting parts of each chamber 5, and the inside of each chamber 5 becomes an independent sealed space when the gate valves 6 thereof are in a closed state. Further, a vacuum pump (not illustrated) is connected to each chamber 5, and the inside of each chamber 5 is decompressed to a decompressed state by the operation of the vacuum pump.

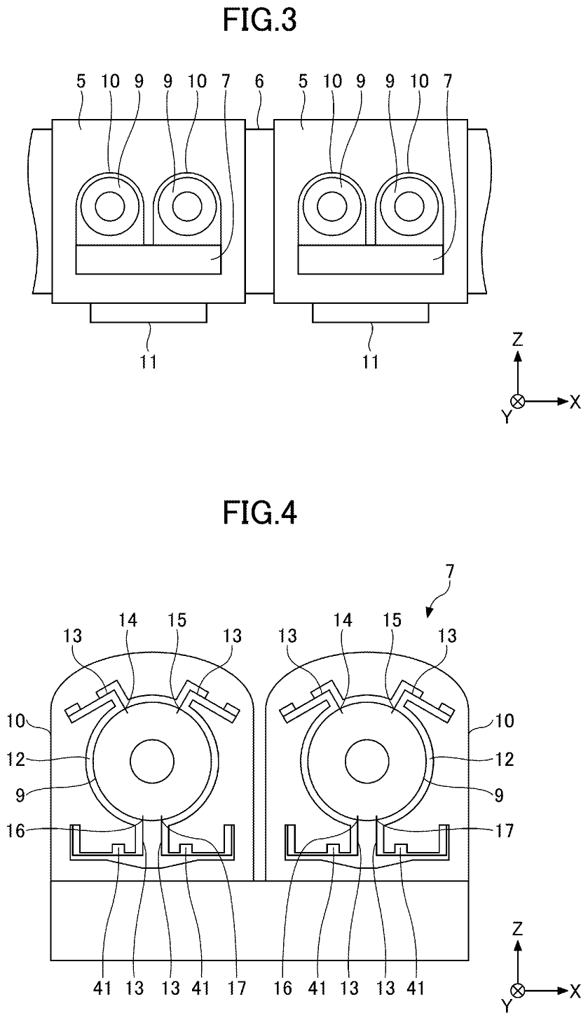

The soft magnetic layer 81, the intermediate layer 82, the recording magnetic layer 83, and the protective layer 84 are successively formed on both of the mutually opposite surfaces of the disk-shaped substrate 9 held by the carrier 7 in the chambers 5, while the carrier 7 is successively transported through the chambers 5 by a transport mechanism (transport mechanism 11 illustrated in FIG. 3). After the protective layer 84 is formed on the disk-shaped substrate 9, the disk-shaped substrate 9 is unloaded from the in-line film forming apparatus 1, and the lubricant film 85 is formed on formed at mutually opposite outermost surfaces of the magnetic recording medium, so as to finally obtain the magnetic recording medium illustrated in FIG. 1.

Moreover, by providing a heat treatment chamber for performing the heat treatment on the disk-shaped substrate 9 as the chamber 5, the heat treatment is performed on the disk-shaped substrate 9 before or after a film formation (film forming process or step) of each layer. Each corner chamber 4 changes a moving direction of the carrier 7, and a mechanism for rotating the carrier 7 is provided inside each corner chamber 4 to rotate the carrier 7 so as to enable the carrier 7 to move to the next chamber 5.

FIG. 3 is a side view of the chamber 5 of the film forming apparatus according to one embodiment. The in-line film forming apparatus 1 includes a linear motor driving mechanism which is driven in a contactless state, for example, as a transport mechanism 11 which transports the carrier 7.

The linear motor driving mechanism includes a plurality of magnets having north poles (N-poles) and south poles (S-poles) thereof alternately arranged at a lower part of the carrier 7, and a rotary magnet having N-poles and S-poles thereof alternately arranged in a spiral shape along a transport path under the plurality of magnets via a partition wall. The linear motor driving mechanism transports the carrier 7 by rotating the rotary magnet around a shaft, while magnetically coupling the plurality of magnets on the side of the carrier 7 and the rotary magnet in a contactless manner.

FIG. 4 is a side view of the carrier 7 of the film forming apparatus according to one embodiment. The carrier 7 is provided with a substrate holder 10 for holding the disk-shaped substrate 9 in a vertical position. The vertical position refers to a state where a principal surface (the upper surface or the lower surface in FIG. 1) of the disk-shaped substrate 9 is parallel to a direction of the gravity. In the present embodiment, two substrate holders 10 are provided on the carrier 7, but the number of substrate holders 10 provided on the carrier 7 is not particularly limited.

The substrate holder 10 holds the disk-shaped substrate 9 in a detachable manner in an opening 12 provided on an inner side of the substrate holder 10. A plurality of support members 13 is provided around the opening 12 of the substrate holder 10, so as to be elastically deformable. The plurality of support members 13 make contact with an outer peripheral end of the disk-shaped substrate 9, and support the disk-shaped substrate 9 fitted inside the opening 12. In the present embodiment, four support members 13 are attached to the substrate holder 10, but three or more support members 13 are sufficient for the purposes of stably holding the disk-shaped substrate 9 inside the opening 12.

Among the four support members 13, the two support members 13 located on the upper side in a vertical direction Z support a first outer peripheral end 14 of the disk-shaped substrate 9 located on the upper left side in the vertical direction Z, and a second outer peripheral end 15 of the disk-shaped substrate 9 located on the upper right side in the vertical direction Z, respectively. In addition, among the four support members 13, remaining two support members 13 located on the lower side in the vertical direction Z support a third outer peripheral end 16 of the disk-shaped substrate 9 located on the lower left side in the vertical direction Z, and a fourth outer peripheral end 17 located on the lower right side in the vertical direction Z, respectively.

The support member 13 is a leaf spring member bent in an L-shape or a U-shape, for example. A base end of the support member 13 is fixed to a main body of the substrate holder 10, and a tip end of the support member 13 protrudes toward the inside of the opening 12. The support members 13 are disposed in passages formed around the opening 12. A V-shaped groove or a U-shaped groove, configured to engage the outer peripheral end of the disk-shaped substrate 9 in order to prevent the disk-shaped substrate 9 from falling, is formed at the tip end of the support member 13.

Two lower passages among the four passages formed around the opening 12 are provided with release holes 41 for releasing the support of the disk-shaped substrate 9 by the support member 13. Release rods (not illustrated) for releasing the support of the disk-shaped substrate 9 by the support members 13 by pushing the support members 13 downward, are inserted into the two release holes 41.

The disk-shaped substrate 9 is attached to and detached from the substrate holder 10 by the substrate attaching and detaching robot 2, such as an articulated robot or the like. When loading the disk-shaped substrate 9, the substrate attaching and detaching robot 2 inserts the disk-shaped substrate 9 suspended from a substrate holding member (not illustrated) into the opening 12 of the substrate holder 10, in a state where two release rods are inserted into the two release holes 41 to push down the two lower support members 13. Then, by releasing the pushing of the support members 13 downward by the two release rods, the two lower support members 13 return to original positions thereof, so that the four support members 13 support the disk-shaped substrate 9.

When unloading the disk-shaped substrate 9, the substrate attaching and detaching robot 2 inserts the substrate holding member (not illustrated) into a hole of the disk-shaped substrate 9 so as not to make contact with a portion of the disk-shaped substrate 9 defining the hole of the disk-shaped substrate 9. Then, the two release rods are inserted into the two release holes 41 to push down the two lower support members 13 and release the support of the disk-shaped substrate 9 by the four support members 13, so that the substrate attaching and detaching robot 2 suspends the disk-shaped substrate 9 from the substrate holding member (not illustrated). The substrate attaching and detaching robot 2 unloads the disk-shaped substrate 9 from the substrate holder 10 so that the disk-shaped substrate 9 does not collide with the support members 13.

### Configuration Example of Heat Treatment Chamber

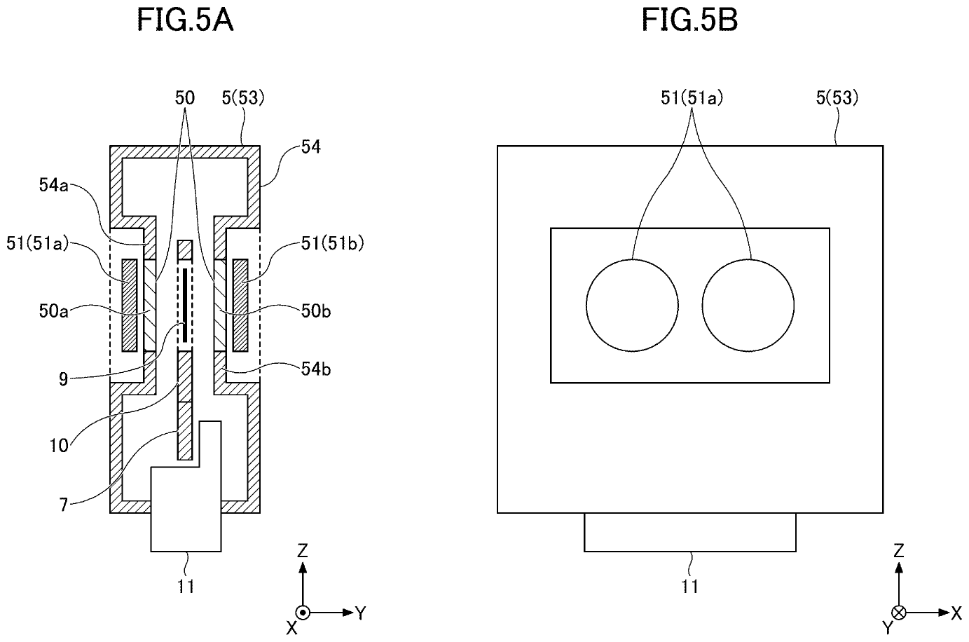

FIG. 5A is a cross sectional view of a heat treatment chamber 53 according to one embodiment, and FIG. 5B is a side view of the heat treatment chamber 53 according to one embodiment. The plurality of chambers 5 include at least one or more heat treatment chambers 53. The heat treatment chamber 53 is a chamber for performing the heat treatment on the disk-shaped substrate 9. The heat treatment chamber 53 includes a chamber housing 54 surrounding the disk-shaped substrate 9, and light transmitting windows 50 forming a part of the chamber housing 54.

In addition, the heat treatment chamber 53 includes light emitting diode (LED) light sources 51 configured to perform the heat treatment on the disk-shaped substrate 9 disposed inside the chamber housing 54 through the light transmitting windows 50. That is, the LED light sources 51 are provided on an outer side of the chamber housing 54. A controller (not illustrated) is connected to the LED light sources 51 to supply on-off signals to each of LED elements forming the LED light sources 51. The controller controls voltages by a Pulse Width Modulation (PWM) or the like, for example, so as to module each of the LED elements.

Because the heat treatment chamber 53 includes the LED light sources 51 disposed on the outer side of the chamber housing 54, the degassing from the LED light sources 51 will not adversely affect the heat treatment on the disk-shaped substrate 9. Further, because each of the LED elements forming the LED light sources 51 can emit light with a directivity, directivities of the heat rays emitted from the LED light sources 51 are also higher than that of other heating means. Accordingly, by concentrating the heat rays on the disk-shaped substrate 9 so as not to hit members other than the disk-shaped substrate 9, such as the substrate holder 10, the carrier 7, an inner wall of the chamber housing 54, or the like, it is possible to reduce the degassing which would otherwise adversely affect the heat treatment on the disk-shaped substrate 9.

The carrier 7 to be transferred into the heat treatment chamber 53 has a structure in which the outer peripheral end of the disk-shaped substrate 9 is supported by the plurality of support members 13, and the disk-shaped substrate 9 is held inside the opening 12 of the substrate holder 10 to which the plurality of support members 13 are attached. Accordingly, the LED light sources 51 can efficiently irradiate the heat rays onto the disk-shaped substrate 9. That is, because the disk-shaped substrate 9 and the substrate holder 10 are separated from each other, it is possible to prevent the light from the LED light sources 51 from being irradiated onto the substrate holder 10. In addition, it is possible to reduce the heat applied to the disk-shaped substrate 9 from being transferred to the substrate holder 10.

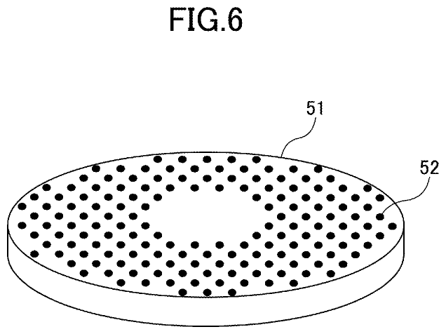

FIG. 6 is a perspective view of the LED light source 51 used in the heat treatment chamber 53 according to one embodiment. The LED light source 51 is formed by a large number of LED elements 52 attached to a main body of the LED light source 51, as illustrated in FIG. 6. Each of the LED elements 52 is disposed so that the emitted light has a directivity in a direction perpendicular to a surface of the main body of the LED light source 51 as a center axis thereof. The directivity of the LED element 52 is preferably ±60° or less with respect to the center axis thereof.

An angle of the directivity of the LED element 52 is defined as an angle with respect to the center axis at which an illuminance becomes 50%, in a case where a position where the LED element 52 emits the brightest light is regarded as the center axis and the illuminance at the center axis is regarded as 100%. Because the hole is provided at a center of the disk-shaped substrate 9, the LED elements 52 are not provided near the center of the main body in the LED light source 51 illustrated in FIG. 6.

Referring again to FIG. 5A, in the heat treatment chamber 53, a positional relationship of the LED light sources 51 and the disk-shaped substrate 9 is preferably set, so that 50% or more of the light from the LED light sources 51, which passes through the light transmitting windows 50, is directly irradiated onto the disk-shaped substrate 9. Because 50% or more of the light from the LED light sources 51 is directly irradiated onto the disk-shaped substrate 9, the light from the LED light sources 51 is prevented from heating members other than the disk-shaped substrate 9, and the degassing inside the heat treatment chamber 53 can be reduced.

Moreover, it is preferable to perform the heat treatment on both the mutually opposite surfaces of the disk-shaped substrate 9, by attaching the LED light sources 51 to both sides of the chamber housing 54. More particularly, the chamber housing 54 includes a first wall 54a, and a second wall 54b disposed to oppose the first wall 54a. The light transmitting windows 50 include a first light transmitting window 50a forming a part of the first wall 54a, and a second light transmitting window 50b forming a part of the second wall 54b and disposed to oppose the first light transmitting window 50a.

The LED light sources 51 include a first LED light source 51a for irradiating one of the mutually opposite surfaces of the disk-shaped substrate 9 with light through the first light transmitting window 50a, and a second LED light source 51b for irradiating the other of the mutually opposite surfaces of the disk-shaped substrate 9 with light through the second light transmitting window 50b. That is, both the mutually opposite surfaces of the disk-shaped substrate 9 are subjected to the heat treatment by the first LED light source 51a and the second LED light source 51b attached to both sides of the chamber housing 54, respectively.

A rate of temperature rise of the disk-shaped substrate 9 can be increased by performing the heat treatment on both the mutually opposite surfaces of the disk-shaped substrate 9 by the first LED light source 51a and the second LED light source 51b disposed on both sides of the chamber housing 54. Hence, it is possible to provide the in-line film forming apparatus 1 capable of setting heat treatment conditions with a large degree of freedom.

A distance (or separation) between the disk-shaped substrate 9 and each of the LED light sources 51 is preferably less than or equal to 50 mm. By setting the distance between the disk-shaped substrate 9 and each of the LED light sources 51 to less than or equal to 50 mm, it is possible to further reduce spreading of the heat rays from the LED light sources 51. Because the light from the LED light sources 51 is prevented from heating members other than the disk-shaped substrate 9, the degassing inside the heat treatment chamber 53 can be reduced.

In addition, the LED light sources 51 preferably emit light having a center wavelength less than 500 nm, and the light transmitting windows 50 are preferably formed of silica. The light having the center wavelength less than 500 nm efficiently heats at least one of the metal elements, such as Fe, Pt, Co, or the like, included in large amounts inside the films or layers of the magnetic recording medium. Moreover, silica transmits 80% or more of the light having the center wavelength less than 500 nm, and has an excellent heat resistance and an excellent strength. Further, quartz is preferable for use as the light transmitting windows 50 because the amount of degassing emitted from quartz is small compared to the degassing emitted from other materials.

### Substrate Heating Method

A substrate heating method preferably includes the following processes or steps, however, the order of the processes or steps is not particularly limited.

### <Heating Process>

The heat treatment chamber 53 performs the heat treatment on the disk-shaped substrate 9, by irradiating the light from the LED light sources 51 provided on the outer side of the chamber housing 54 surrounding the disk-shaped substrate 9, through the light transmitting windows 50 forming a part of the chamber housing 54, onto the disk-shaped substrate 9 disposed inside the chamber housing 54.

The heat treatment chamber 53 preferably directly irradiates 50 % or more of the light from the LED light sources 51 passed through the light transmitting windows 50. Further, the heat treatment chamber 53 preferably performs the heat treatment on both the mutually opposite surfaces of the disk-shaped substrate 9, by the first LED light source 51a and the second LED light source 51b provided on both sides of the chamber 54, through the first light transmitting window 50a and the second light transmitting window 50b, respectively.

### <Preparation Process>

The substrate heating method preferably includes a preparation process or step that sets the distance between the disk-shaped substrate 9 and each of the LED light sources 51 to less than or equal to 50 mm. In addition, the preparation process or step preferably includes a process or step to set the center wavelength of the light emitted from the LED light sources 51 to less than 500 nm and forming the light transmitting windows 50 from silica.

### Advantageous Features of Present Embodiment

The in-line film forming apparatus 1 according to the present embodiment can provide the following advantageous features. Because the heat treatment chamber 53 is provided with the LED light sources 51 on the outer side of the chamber housing 54, the degassing from the LED light sources 51 does not adversely affect the heat treatment on the disk-shaped substrate 9. In addition, because the directivity of the heat rays emitted from the LED light sources 51 is high, the heat rays can be concentrated on the disk-shaped substrate 9 so as not to be applied on the members other than the disk-shaped substrate 9, thereby reducing the degassing which would otherwise adversely affect the heat treatment on the disk-shaped substrate 9. Hence, it is possible to improve the quality of the films or layers formed on the disk-shaped substrate 9.

The carrier 7 transferred into the heat treatment chamber 53 has a structure in which the outer peripheral end of the disk-shaped substrate 9 is supported by the plurality of support members 13 and held inside the opening 12 of the substrate holder 10 to which the plurality of support members 13 are attached, and the disk-shaped substrate 9 and the substrate holder 10 are separated from each other. For this reason, the light from the LED light sources 51 can be prevented from being irradiated on the substrate holder 10. In addition, it is possible to reduce the heat applied to the disk-shaped substrate 9 from being transferred to the substrate holder 10.

Further, 50 % or more of the light from the LED light source, 51, passed through the light transmitting windows 50, is directly irradiated onto the disk-shaped substrate 9. Accordingly, it is possible to prevent the light from the LED light sources 51 from heating the members other than the disk-shaped substrate 9. Hence, degassing inside the heat treatment chamber 53 can be reduced.

Moreover, by setting the distance between the disk-shaped substrate 9 and each of the LED light sources 51 less than or equal to 50 mm, it is possible to further reduce the spreading of the heat rays from the LED light sources 51. Hence, because the light from the LED light sources 51 is prevented from heating the members other than the disk-shaped substrate 9, the degassing inside the heat treatment chamber 53 can be reduced.

The LED light sources 51 emit the light having the center wavelength less than 500 nm, and the light transmitting windows 50 are formed of silica. Accordingly, the light transmitting windows 50 can efficiently transmit the light from the LED light sources 51, and the films or layers formed on the disk-shaped substrate 9 can be efficiently heated by the light from the LED light sources 51. In addition, because the light transmitting windows 50 formed of quartz emit a relatively small amount of degassing, the degassing inside the heat treatment chamber 53 can be reduced to improve the quality of the films or layers formed on the disk-shaped substrate 9.

Further, the rate of temperature rise of the disk-shaped substrate 9 can be increased by performing the heat treatment on both the mutually opposite surfaces of the disk-shaped substrate 9 by the first LED light source 51a and the second LED light source 51b disposed on both sides of the chamber housing 54. Hence, it is possible to provide the in-line film forming apparatus 1 capable of setting heat treatment conditions with a large degree of freedom.

According to the present disclosure, it is possible to reduce degassing so as to improve a quality of a film formed on a substrate.

Although the embodiments are described as above, the embodiments are examples and the present invention is not limited to such embodiments. The embodiments may be implemented in various other forms, and various combinations, omissions, substitutions, modifications, or the like may be made without departing from the scope of the present invention. The embodiments and modifications thereof fall within the scope of the claimed invention and equivalents thereof.

For example, the film forming apparatus according to the present disclosure is not limited to the in-line film forming apparatus 1, and may be a film forming apparatus of another type, such as a batch-type film forming apparatus or the like. In addition, the substrate of the present disclosure is not limited to the disk-shaped substrate 9 for the magnetic recording medium, and may be a substrate for a semiconductor integrated circuit. Moreover, the shape of the substrate of the present disclosure is not limited to a disk shape.

In addition, the numbers such as ordinal numbers, quantities, units, ranges, or the like used in the description of the embodiments described above are all examples for specifically describing the technique of the present disclosure, and the present disclosure is not limited to the numbers of the examples. Further, a connection relationship between constituent elements or components is illustrated for specifically describing the technique of the present disclosure, and the connection relationship for implementing the functions of the present disclosure is not limited thereto.

What is claimed is:

1. A heat treatment chamber for performing a heat treatment on a substrate, comprising:
a chamber housing surrounding the substrate;
a light transmitting window forming a part of the chamber housing; and
an LED light source, provided on an outer side of the chamber housing, and configured to irradiate light on the substrate arranged inside the chamber housing through the light transmitting window, so to perform the heat treatment on the substrate.

2. The heat treatment chamber as claimed in claim 1, wherein 50 % or more of the light from the LED light source that is transmitted through the light transmitting window is directly irradiated on the substrate.

3. The heat treatment chamber as claimed in claim 1, wherein the LED light source and the substrate are separated by a distance less than or equal to 50 mm.

4. The heat treatment chamber as claimed in claim 1, wherein
the LED light source emits light having a center wavelength less than 500 nm, and
the light transmitting window is formed of silica.

5. The heat treatment chamber as claimed in claim 1, wherein
the chamber housing includes:
a first wall, and
a second wall disposed to oppose the first wall,
the light transmitting window includes:
a first light transmitting window forming a part of the first wall; and
a second light transmitting window forming a part of the second wall, and disposed so as to oppose the first light transmitting window,
the LED light source includes:
a first LED source configured to irradiate the light to a first surface of the substrate through the first light transmitting window, and
a second LED source configured to irradiate the light to a second surface of the substrate, opposite to the first surface of the substrate, through the second light transmitting window, and
the heat treatment is performed on both the first surface and the second surface of the substrate by the first LED light source and the second LED light source disposed on both sides of the chamber housing, respectively.

6. A film forming apparatus comprising:
a heat treatment chamber configured to perform a heat treatment on a substrate;
a carrier configured to support an outer peripheral end portion of the substrate by a plurality of support members inside the heat treatment chamber, and hold the substrate by an opening of a substrate holder to which the plurality of support members are attached;
a transfer mechanism configured to transfer the carrier into the heat treatment chamber,
wherein the heat treatment chamber includes:
a chamber housing surrounding the substrate held by the carrier;
a light transmitting window forming a part of the chamber housing; and
an LED light source, provided on an outer side of the chamber housing, and configured to irradiate light on the substrate arranged inside the chamber housing through the light transmitting window, so to perform the heat treatment on the substrate.

7. The film forming apparatus as claimed in claim 6, wherein 50 % or more of the light from the LED light source that is transmitted through the light transmitting window of the heat treatment chamber is directly irradiated on the substrate.

8. The film forming apparatus as claimed in claim 6, wherein the LED light source and the substrate are separated by a distance less than or equal to 50 mm.

9. The film forming apparatus as claimed in claim 6, wherein
the LED light source emits light having a center wavelength less than 500 nm, and
the light transmitting window is formed of silica.

10. The film forming apparatus as claimed in claim 6, wherein
the chamber housing includes:
a first wall, and
a second wall disposed to oppose the first wall,
the light transmitting window includes:
a first light transmitting window forming a part of the first wall; and
a second light transmitting window forming a part of the second wall, and disposed so as to oppose the first light transmitting window,
the LED light source includes:
a first LED source configured to irradiate the light to a first surface of the substrate through the first light transmitting window, and
a second LED source configured to irradiate the light to a second surface of the substrate, opposite to the first surface of the substrate, through the second light transmitting window, and
the heat treatment is performed on both the first surface and the second surface of the substrate by the first LED light source and the second LED light source disposed on both sides of the chamber housing, respectively.

11. A substrate heating method comprising:
irradiating light from an LED light source provided on an outer side of a chamber housing onto a substrate arranged inside the chamber housing through a light transmitting window, so to perform a heat treatment on the substrate.

12. The substrate heating method as claimed in claim 11, wherein 50 % or more of the light from the LED light source that is transmitted through the light transmitting window is directly irradiated on the substrate.
